(19) United States
(12) Patent Application Publication
(10) Pub. No.: US 2015/0084057 A1
(43) Pub. Date: Mar. 26, 2015

(54) METHOD AND STRUCTURE FOR REDUCING THE PROPAGATION OF CRACKS IN EPITAXIAL FILMS FORMED ON SEMICONDUCTOR WAFERS

(71) Applicant: Raytheon Company, Waltham, MA (US)

(72) Inventor: Kelly P. Ip, Lowell, MA (US)

(73) Assignee: Raytheon Company, Waltham, MA (US)

(21) Appl. No.: 14/032,354

(22) Filed: Sep. 20, 2013

(51) Int. Cl. H01L 21/02; H01L 29/20; H01L 21/306

(52) U.S. Cl. CPC H01L 21/0254; H01L 21/02433; H01L 21/30612; H01L 29/2003
USPC 257/76; 438/8; 257/200

(57) ABSTRACT

A method for reducing the effects of cracks in an epitaxial film. The method includes; providing a semiconductor wafer with an epitaxial film thereon; inspecting the epitaxial film to determine outer peripheral edge regions of the epitaxial film having cracks therein; and selectively removing the determined outer peripheral edge regions of the epitaxial film while leaving portions of the semiconductor wafer underlying the removed determined outer peripheral regions of the epitaxial film.

### TECHNICAL FIELD

This disclosure relates generally to methods and structures for reducing the propagation of cracks in epitaxial films for on semiconductor wafers and more particularly to methods for reducing the propagation of cracks in epitaxial films having a different crystallographic structure than the crystallographic structure of the semiconductor wafer.

### BACKGROUND

As is known in the art, Group III-N epitaxial film growth on Si substrates tend to have high stress developed in the films, leading to crack formation at the edge of the epitaxial layers that may propagate further into interior regions of the epitaxial layer as a result of subsequent processing. During fabrication, the wafers with the epitaxial layers are exposed to subsequent mechanical stress, such as electrostatic chucks, backside vacuum, and robotic vacuum handling, and thermal stresses, such as during thin film deposition and anneal, which can cause the cracks in the edges of the epitaxial film to propagate and degrade the epitaxial film and/or cause wafer breakage.

### SUMMARY

In accordance with the present disclosure, a method is provided comprising: providing a semiconductor wafer with an epitaxial film thereon; inspecting the epitaxial film to determine outer peripheral edge regions of the epitaxial film having cracks therein; and selectively removing the determined outer peripheral edge regions of the epitaxial film while leaving portions of the semiconductor wafer underlying the removed determined outer peripheral regions of the epitaxial film.

In one embodiment, the epitaxial film has a different crystallographic structure than the crystallographic structure of the semiconductor wafer.

In one embodiment, the wafer is silicon and the epitaxial film is a compound of nitrogen.

In one embodiment, the wafer is silicon and the epitaxial film is a Group III-N material.

In one embodiment, the wafer is silicon and the epitaxial film is a Gallium Nitride.

In one embodiment, the silicon is <111> silicon.

In one embodiment a method is provided comprising: providing a semiconductor wafer with an epitaxial film thereon, the epitaxial film having outer peripheral regions with cracks therein; and selectively removing peripheral regions of the epitaxial film while leaving portions of the semiconductor wafer underlying the removed determined outer peripheral regions of the epitaxial film.

In one embodiment, a semiconductor structure is provided, comprising: a semiconductor wafer, the wafer having an outer peripheral edge; and an epitaxial film disposed on and in direct contact with a central portion of the semiconductor wafer and being displaced a predetermined distance from the peripheral edge of the wafer.

With such method, the cracked edges of III-N epitaxial films are removed from the Si substrates. As a result, the edge cracks are eliminated and no longer propagate through the epitaxial film during subsequent processing.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIGS. 1A-1D are diagrammatical cross sectional sketches, greatly exaggerated in scale, taken along a diameter of a circular semiconductor wafer, showing a method for reducing the propagation of cracks in epitaxial films formed on a surface of the semiconductor wafer according to the disclosure.

Like reference symbols in the various drawings indicate like elements.

### DETAILED DESCRIPTION

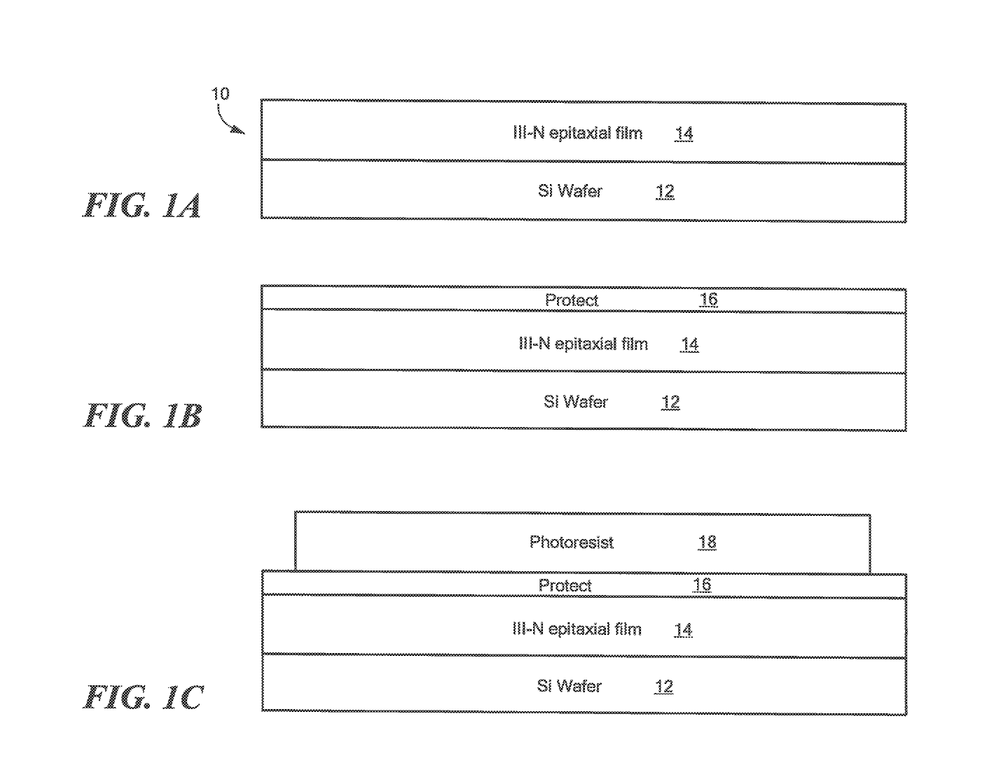

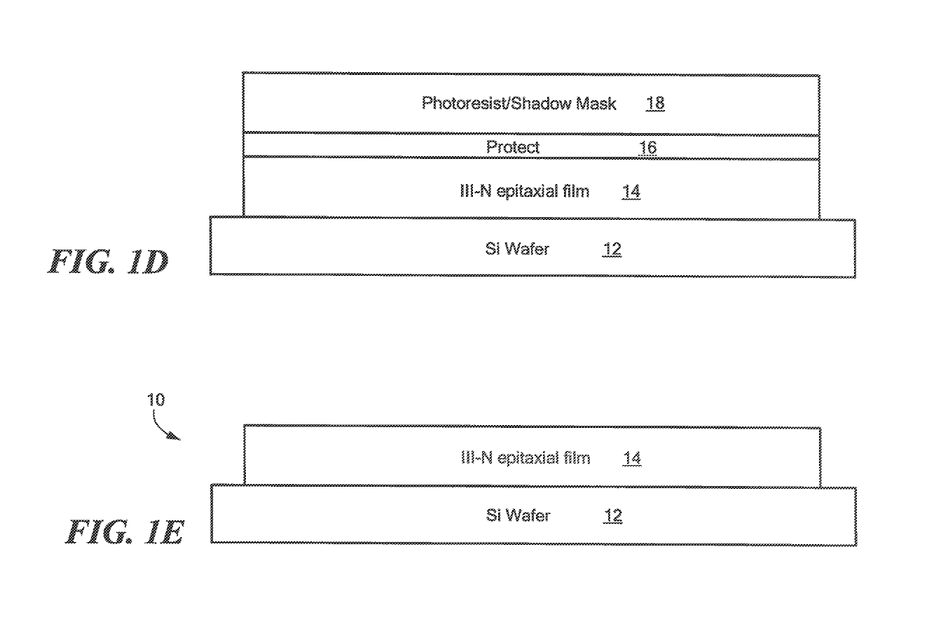

Referring now to FIG. 1A, a structure 10 having a semiconductor wafer 12, here a <111> silicon wafer having a diameter of here, for example, an eight inch diameter circular wafer is shown. The wafer 12 has an epitaxial film 14, here a compound of nitrogen, for example a Group III-N film, such as GAN which may include layers of AlGaN, for example. After obtaining the structure 10 having the wafer 10 and the epitaxial film 14 thereon is inspected for cracks in outer peripheral edges of the epitaxial film 12. These cracks may exist inwardly from the edges up to 5 mm (0.197 inches). The inspection is used to determine how from the edges the cracks have propagated into interior regions of the epitaxial film 14. Once this is determined, a protective layer 16 (FIG. 1B) for the epitaxial layer 14 is formed over the upper surface of the epitaxial film 16. The protection layer 16 may be for example, a dielectric such as Atomic Layer Deposited (ALD) Al₂O₃, It is noted that the use of the protective layer 16 is an optional step in the process.

Next, referring to FIG. 1C, the protective layer 16 is coated with a photoresist layer 18, for example, SPR-220 photoresist, and patterned, using any conventional photolithographic process or etch bead removal process, to leave a portion of the photoresist 18 over the interior portions of the epitaxial film 14 and remove portions of the photoresist 18 from regions about the outer edge peripheral regions 20 of the epitaxial film 14 where the cracks in the epitaxial film 14 were determined to exist, as shown in FIG, 1C. It is understood that if the protective layer 16 is not used, the photoresist layer 18 would be deposited directly to the surface of the epitaxial layer 14 and the photolithographically processed as described above. Alternatively, a shadow mask. can be used to expose the edge of the wafer.

Next, and referring to FIG. 1D, the surface of the structure shown in FIG. 1C is plasma etched in chlorine-based chemistry to remove portions of the protective layer 16 and underlying portions of the epitaxial film 14 exposed by the photoresist layer 18. It is noted that to insure complete removal of the exposed portions of the epitaxial film 16, the etch process may remove a small upper exposed surface portion of the wafer 12. Thus, the process selectively removes the determined outer peripheral edge regions of the epitaxial film while leaving portions of the semiconductor water underlying the removed determined outer peripheral regions of the epitaxial film. Thus, a semiconductor structure (FIG. 1E) is provided having the semiconductor wafer 12 having an outer peripheral edge; and the epitaxial film 14 disposed on and in direct contact with a central portion of the semiconductor wafer 12 and being displaced a predetermined distance from the peripheral edge of the wafer 12. The resulting structure, shown in FIG. 1E, with the edge cracks now removed from the outer peripheral edge portions of the epitaxial layer is now ready for further processing.

A number of embodiments of the disclosure have been described. Nevertheless, it will be understood that various modifications may be made without departing from the spirit and scope of the disclosure. Accordingly, other embodiments are within the scope of the following claims.

What is claimed is:

1. A method comprising:
providing a semiconductor wafer with an epitaxial film thereon;
inspecting the epitaxial film to determine outer peripheral edge regions of the epitaxial film having cracks therein; and
selectively removing the determined outer peripheral edge regions of the epitaxial film while leaving portions of the semiconductor wafer underlying the removed determined outer peripheral regions of the epitaxial film.

2. The method recited in claim I wherein the epitaxial film has a different crystallographic structure than the crystallographic structure of the semiconductor wafer.

3. The method recited in claim 2 wherein the wafer is silicon and the epitaxial film is a compound of nitrogen.

4. The method recited in claim 2 wherein the wafer is silicon and the epitaxial film is a Group III-N material.

5. The method recited in claim 1 wherein the wafer is silicon and the epitaxial film is Gallium Nitride, Indium Gallium Nitride, Aluminum Nitride or Aluminum Indium Gallium Nitride.

6. The method recited in claim. 5 wherein the silicon has a <111> silicon.

7. A method comprising:
providing a semiconductor wafer with an epitaxial film thereon, the epitaxial film having outer peripheral regions with cracks therein;
selectively removing peripheral regions of the epitaxial film while leaving portions of the semiconductor wafer underlying the removed determined outer peripheral regions of the epitaxial film.

8. The method recited in claim 7 wherein the epitaxial film has a different crystallographic structure than the crystallographic structure of the semiconductor wafer.

9. The method recited in claim 8 wherein the wafer is silicon and the epitaxial film is a compound of nitrogen.

10. The method recited in claim 8 wherein the wafer is silicon and the epitaxial film is a Group III-N material,

11. The method recited in claim 7 wherein the wafer is silicon and the epitaxial film is Gallium Nitride, Indium Gallium Nitride, Aluminum Nitride or Aluminum Indium Gallium Nitride.

12. The method recited in claim 11 wherein the silicon has a <111> silicon.

13. A semiconductor structure comprising:
a semiconductor wafer, the wafer having an outer peripheral edge;
an epitaxial film disposed on and in direct contact with a central portion of the semiconductor wafer and being displaced a predetermined distance from the peripheral edge of the wafer.

14. The semiconductor structure recited in claim 13 wherein the epitaxial film has a different crystallographic structure than the crystallographic structure of the semiconductor wafer.

15. The semiconductor structure recited in claim 14 wherein the wafer is silicon and the epitaxial film is a compound of nitrogen.

16. The semiconductor structure recited in claim 14 wherein the wafer is silicon and the epitaxial film is a Group III-N material.

17. The semiconductor structure recited in claim 13 wherein the wafer is silicon and the epitaxial film is Gallium Nitride, Indium Gallium Nitride, Aluminum Nitride or Aluminum Indium Gallium Nitride.

18. The semiconductor structure recited in claim 17 wherein the silicon has a <111> silicon.
